(19) United States
(12) Patent Application Publication
(10) Pub. No.: US 2021/0289667 A1
(43) Pub. Date: Sep. 16, 2021

(54) ELECTRONIC ASSEMBLY AND HEAT DISSIPATION ASSEMBLY THEREOF

(71) Applicants: Inventec (Pudong) Technology Corporation, Shanghai (CN); INVENTEC CORPORATION, Taipei (TW)

(72) Inventor: Ming-Hung SHIH, Taipei (TW)

(21) Appl. No.: 16/902,719

(22) Filed: Jun. 16, 2020

(30) Foreign Application Priority Data
Mar. 10, 2020 (CN) 202010163613.2

(51) Int. Cl. H05K 7/20; H01L 23/427

(52) U.S. Cl. CPC H05K 7/20418; H01L 23/427

(57) ABSTRACT

An electronic assembly and a heat dissipation assembly thereof. The electronic assembly includes a circuit board and a heat dissipation assembly. The circuit board includes a plate body and a heat source disposed on the plate body. The heat dissipation assembly includes a fin assembly, a mounting plate body, and a heat dissipation pillar. The mounting plate body is fixed to the fin assembly and includes a mounting hole. The heat dissipation pillar is engaged in the mounting hole of the mounting plate body. One end of the heat dissipation pillar is in thermal contact with the fin assembly, and another end of the heat dissipation pillar is in thermal contact with the heat source of the circuit board.

### CROSS-REFERENCE TO RELATED APPLICATIONS

This non-provisional application claims priority under 35 U.S.C. § 119(a) on Patent Application No(s). 202010163613.2 filed in China, on Mar. 10, 2020, the entire contents of which are hereby incorporated by reference.

### BACKGROUND OF THE INVENTION

### Technical Field of the Invention

The invention relates to an electronic assembly and a heat dissipation assembly thereof.

### Description of the Related Art

In general, in an electrical/electronic system, there can be a fin set employed for dissipating heat generate by a heat source disposed on a circuit board, where the fin set is usually disposed on the circuit board or mounted on the casing of the system. Also, in order to improve the heat transfer efficiency from the heat source to the fin set, there are heat dissipation pillars that are in direct thermal contact with the heat source and the fin set. Typically, there are two ways to form or install the heat dissipation pillars, one is to integrally form the heat dissipation pillars with the fin set, and the other is to fix the heat dissipation pillars to the fin set via screws. However, these ways will increase the cost when applied for multiple heat sources.

Specifically, the heat dissipation pillars and the fin set can be integrally formed by an extrusion process, but the just-formed pillars need additional machining processes to turn them into the desired shape or size, which significantly increases cost and can cause the fin assembly or the heat dissipation pillar can hardly be commonly used or modularized and mass production thereof is hard to be performed either. In the other case, screwing the heat dissipation pillars one by one not only involves troublesome steps to increase the cost in assembly line but also can reduce the yield rate.

### SUMMARY OF THE INVENTION

One aspect of the invention is to provide an electronic assembly and a heat dissipation assembly thereof that allow heat to be transferred from the electronic assembly to the heat dissipation assembly in an effective manner and to allow the heat dissipation pillars of the heat dissipation assembly to be assembled to the fin assembly by a tool-less manner without using screws, thereby further reducing the manufacturing and assembling cost of the heat dissipation assembly.

Another aspect of the invention is to provide several heat dissipation pillars that are adaptive to the height or contact area of each heat source of the electronic assembly.

Still another aspect of the invention is to provide a heat dissipation pillar that is a heat pipe structure so that the heat conduction thereof is improved to allow the heat source of the electronic assembly to have better heat dissipation condition.

One embodiment of this invention provides an electronic assembly including a circuit board and a heat dissipation assembly. The circuit board includes a plate body and a heat source disposed on the plate body. The heat dissipation assembly includes a fin assembly, a mounting plate body, and a heat dissipation pillar. The mounting plate body is fixed to the fin assembly and includes a mounting hole. The heat dissipation pillar is engaged in the mounting hole of the mounting plate body. One end of the heat dissipation pillar is in thermal contact with the fin assembly, and another end of the heat dissipation pillar is in thermal contact with the heat source of the circuit board.

Another embodiment of this invention provides a heat dissipation assembly configured to be in thermal contact with a heat source and including a fin assembly, a mounting plate body and a heat dissipation pillar. The mounting plate body is fixed to the fin assembly and includes a mounting hole. The heat dissipation pillar is engaged in the mounting hole of the mounting plate body. One end of the heat dissipation pillar is in thermal contact with the fin assembly, and another end of the heat dissipation pillar is configured to be in thermal contact with the heat source.

Still another embodiment of this invention provides a heat dissipation assembly configured to be in thermal contact with a heat source and including a fin assembly, a mounting plate body and a heat dissipation pillar. The mounting plate body is thermally conductive and fixed to the fin assembly. The heat dissipation pillar is adhered to the mounting plate body. One end of the heat dissipation pillar is in thermal contact with the fin assembly, and another end of the heat dissipation pillar is configured to be in thermal contact with the heat source.

According to the electronic assembly and the heat dissipation assembly thereof discussed above, the heat dissipation pillars can be partially engaged into the mounting holes of the mounting plate body and therefore to be fixed to the mounting plate body of the fin assembly without using screws. As such, compared to the case that the fin assembly and the heat dissipation pillars are integrally formed, the heat dissipation pillars of the heat dissipation assembly of the invention do not need machining process during manufacturing.

In addition, compared to the case that screwing the heat dissipation pillars one by one, the installation of the heat dissipation pillars of the heat dissipation assembly of the invention is more convenient and efficient.

Accordingly, the heat dissipation assembly of the invention does not involve complex machining process and is convenient and efficient in assembly process, and thus the overall manufacturing cost can be reduced.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a perspective view of an electronic assembly according to an embodiment of the invention;

FIG. 2 is an exploded view of the electronic assembly in FIG. 1;

FIG. 3 is a cross-sectional view of the electronic assembly in FIG. 1;

FIG. 4 is a cross-sectional view of an electronic assembly according to another embodiment of the invention;

FIG. 5 is a cross-sectional view of a mounting plate body and a heat dissipation pillar according to still another embodiment of the invention; and

FIG. 6 is a cross-sectional view of a mounting plate body and a heat dissipation pillar according to still yet another embodiment of the invention.

### DETAILED DESCRIPTION

In the following detailed description, for purposes of explanation, numerous specific details are set forth in order to provide a thorough understanding of the disclosed embodiments. It will be apparent, however, that one or more embodiments can be practiced without these specific details. In other instances, well-known structures and devices are schematically shown in order to simplify the drawing.

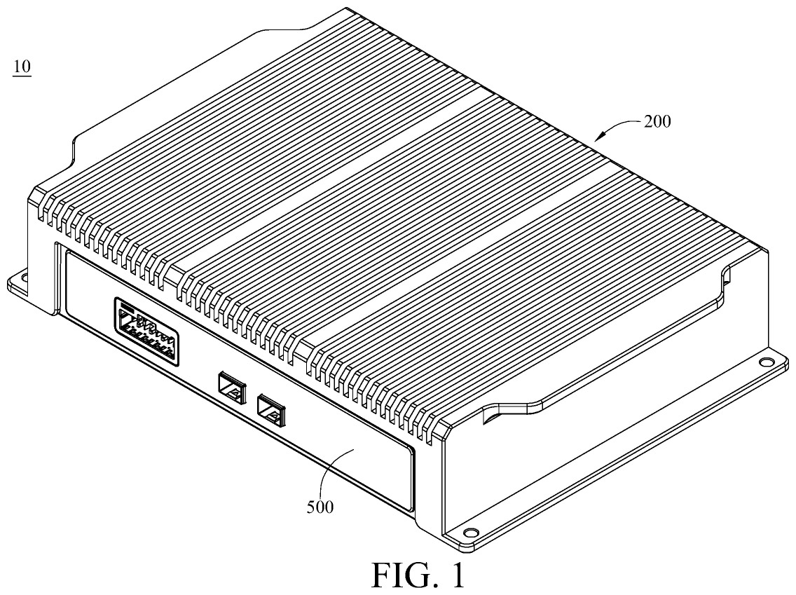

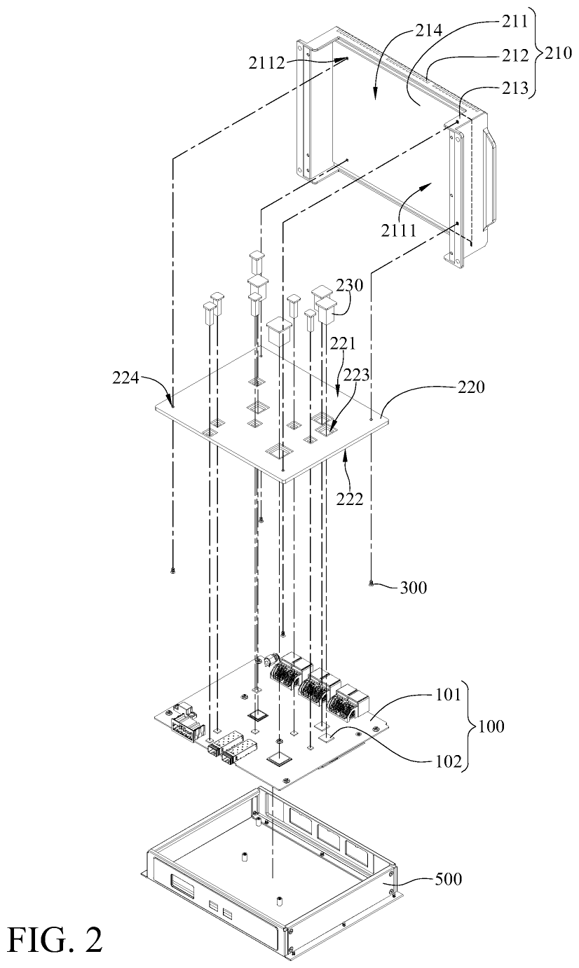

Please refer to FIG. 1 and FIG. 2, there are shown a perspective view of an electronic assembly according to an embodiment of the invention and an exploded view of the electronic assembly.

In this embodiment, the electronic assembly 10 includes a circuit board 100, a heat dissipation assembly 200, a plurality of fasteners 300, a thermal grease 400, and a base 500.

The circuit board 100 includes a plate body 101 and a plurality of heat sources 102. The heat sources 102 are disposed on the plate body 101 and are, for example, central processing units (CPUs).

The heat dissipation assembly 200 includes a fin assembly 210, a mounting plate body 220, and a plurality of heat dissipation pillars 230. In this embodiment, the fin assembly 210 includes a base portion 211, a plurality of fins 212, and two sidewalls 213. In this embodiment, the base portion 211 includes a first side surface 2110, a second side surface 2111, and a plurality of first holes 2112, where the first holes 2112 are, for example, screw holes. The first side surface 2110 and the second side surface 2111 face away from each other. The first holes 2112 are located on the second side surface 2111. The fins 212 protrude from the first side surface 2110. The sidewalls 213 stand on the second side surface 2111. The sidewalls 213 and the base portion 211 together form an accommodation space 214 therebetween.

The mounting plate body 220 is fixed on the second side surface 2111 and is located in the accommodation space 214. Also, the mounting plate body 220 is formed by, for example, aluminum extrusion. In this embodiment, the mounting plate body 220 includes a third side surface 221, a fourth side surface 222, a plurality of mounting holes 223, and a plurality of second holes 224, where the second holes 224 are, for example, screw holes. The third side surface 221 faces away from the fourth side surface 222. The mounting holes 223 and the second holes 224 penetrate through the third side surface 221 and the fourth side surface 222.

In this embodiment, these fasteners 300 are, for example, screws, and are respectively disposed through the first holes 2112 of the base portion 211 of the fin assembly 210 and the second holes 224 of the mounting plate body 220 so as to fix the third side surface 221 of the mounting plate body 220 on the second side surface 2111 of the base portion 211 of the fin assembly 210. Note that the fixation between the mounting plate body 220 and the base portion 211 is not restricted to screws. In other embodiments, the mounting plate body and the base portion can be fixed to each other by welding.

In addition, the invention is not limited by the configuration of the fin assembly 210. In other embodiments, the fin assembly does not include the aforementioned sidewalls and thus does not have the aforementioned accommodation space, and the mounting plate body can be fixed on the second side surface and protrudes from the fin assembly.

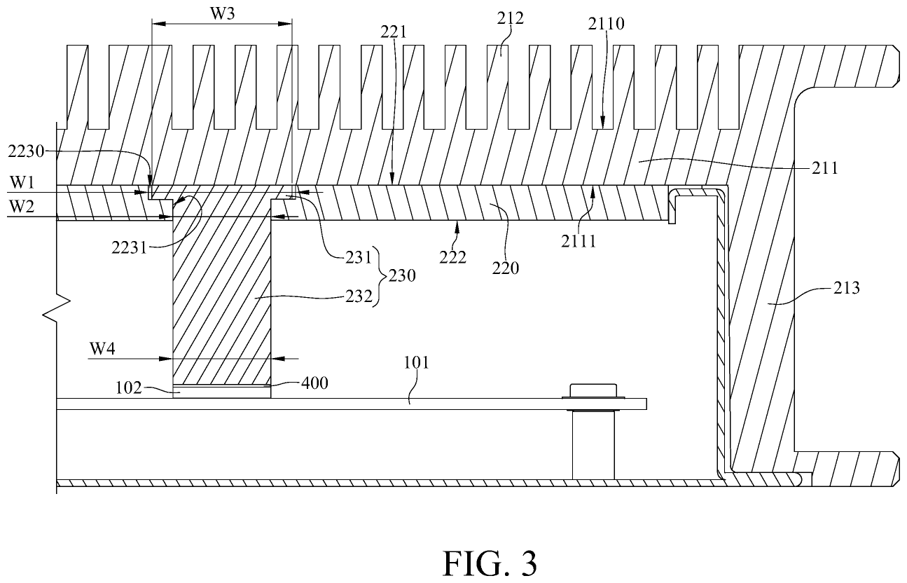

Please additionally refer to FIG. 3 that is a cross-sectional view of the electronic assembly in FIG. 1. In this embodiment, each mounting hole 223 include a wider portion 2230 and a narrower portion 2231 that are connected to each other. A width W1 of the wider portion 2230 is larger than a width W2 of the narrower portion 2231. That is, the mounting hole 223 at least has two widths. The wider portion 2230 is formed at the third side surface 221 of the mounting plate body 220, and the narrower portion 2231 is formed at the fourth side surface 222 of the mounting plate body 220.

The heat dissipation pillars 230 are formed by, for example, aluminum extrusion. One end of the heat dissipation pillar 230 can be in direct thermal contact with the second side surface 2111 of the base portion 211 of the fin assembly 210, and the other end of the heat dissipation pillar 230 can be used to thermally contact with the heat source 102 of the circuit board 100. In this embodiment, each heat dissipation pillar 230 includes a head part 231 and a body part 232 that are connected to each other. A width W3 of the head part 231 is larger than a width W4 of the body part 232. That is, each heat dissipation pillar 230 at least has two widths. The width W3 of the head part 231 ranges between the width W1 of the wider portion 2230 of the mounting hole 223 and the width W2 of the narrower portion 2231 of the mounting hole 223, and the width W4 of the body part 232 is smaller than the width W2 of the narrower portion 2231 of the mounting hole 223. Therefore, as shown in FIG. 3, the head part 231 can be placed into the wider portion 2230 of the mounting hole 223 and can be clamped by the fin assembly 210 and the mounting plate body 220, such that the heat dissipation pillar 230 can be firmly fixed at the mounting hole 223 of the mounting plate body 220.

Furthermore, in other embodiments, heat pipes that are embedded into a mounting plate body of thermally conductive material can be implemented as the heat dissipation pillars of the invention. Moreover, note that the heights of the heat dissipation pillars 230 are allowed to be modified to ensure the thermal contact with the heat sources.

Note that the invention is not limited by how the heat dissipation pillar 230 is engaged in the mounting hole 223 of the mounting plate body 220. In other embodiments, the heat dissipation pillar can have a fixed width and can be engaged with the mounting hole in a tight-fit manner, which is described in detail below.

Additionally, note that the quantities of the heat dissipation pillars 230 and the mounting holes 223 are not restricted. In other embodiments, there is only one heat dissipation pillar and one mounting hole on the mount plate body.

Furthermore, the heat dissipation pillars 230 are respectively in thermal contact with the heat sources 102 via the thermal grease 400. The thermal grease 400 can prevent the heat dissipation pillars 230 from directly hitting or pressing the heat sources 102 so as to prevent damage to the heat sources 102.

However, the thermal grease 400 is optional. In other embodiments, there can be no thermal grease existing between the heat dissipation pillars and the heat sources, in such a case, the heat dissipation pillars and the heat sources have or do not have a neglectable air gap that is small enough to not affecting the heat transfer between the heat dissipation pillars and the heat sources.

The base 500 is for the fixation of the plate body 101 of the circuit board 100. Also, the base 500 is fixed to the fin assembly 210. The circuit board 100 is accommodated in a space surrounded by the base 500 and the fin assembly 210. As shown, the base 500 and the fin assembly 210 together form an outer casing of the electronic assembly 10. And the fins 212 of the fin assembly 210 are disposed on the said outer casing and are exposed to the outside. However, the base 500 is optional; in other embodiments, the electronic assembly omits the base 500.

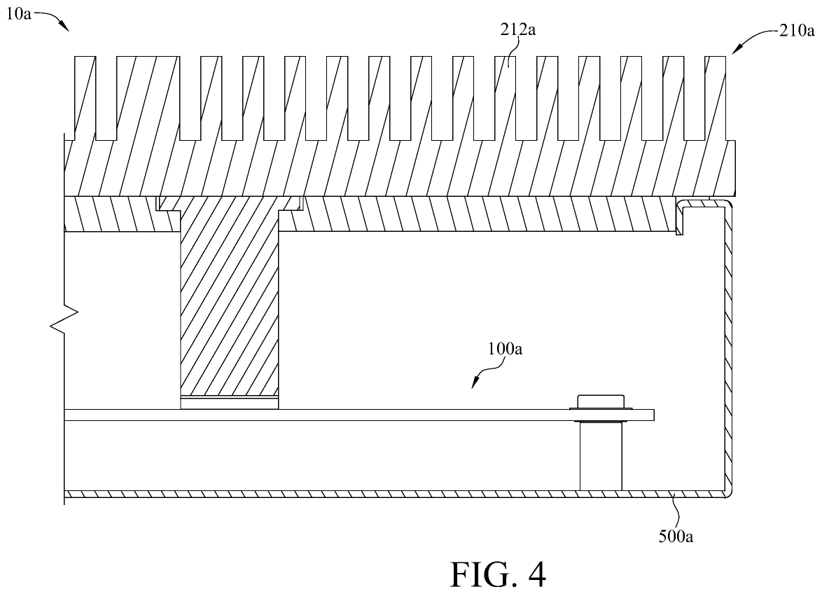

In this embodiment, the base 500 is fixed to the fin assembly 210 and the fins 212 of the fin assembly 210 is disposed on the outer casing together formed by the base 500 and the fin assembly 210, but the invention is not limited thereto. Please refer to FIG. 4, there is shown a cross-sectional view of an electronic assembly 10a according to another embodiment of the invention, the electronic assembly 10a includes a fin assembly 210a disposed on a base 500a or a circuit board 100a. In this arrangement, fins 212a of the fin assembly 210a are disposed in the electronic assembly 10a, and the fin assembly 210a is not disposed on the outer casing of the electronic assembly 10a.

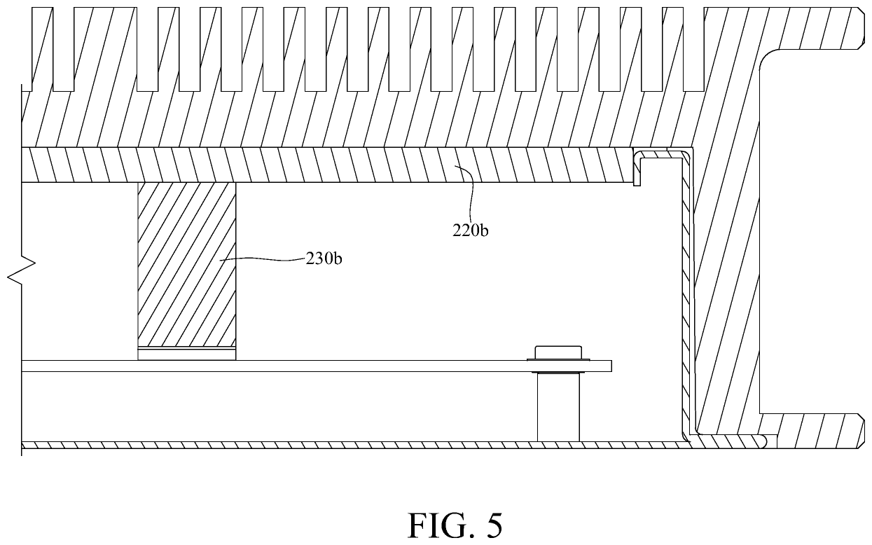

In addition, the invention is not limited by how the heat dissipation pillars 230 are fixed to the mounting plate body 220. In other embodiments, the heat dissipation pillars can be fixed onto the mounting plate body via adhesive, in such a case, the mounting plate body does not have the aforementioned mounting holes. Specifically, please refer to FIG. 5, there is shown a cross-sectional view of a mounting plate body 220b and a heat dissipation pillar 230b according to still another embodiment of the invention, as shown, the mounting plate body 220b does not include the aforementioned mounting hole and the heat dissipation pillar 230b can be fixed to the mounting plate body 220b made of thermally conductive material via adhesive.

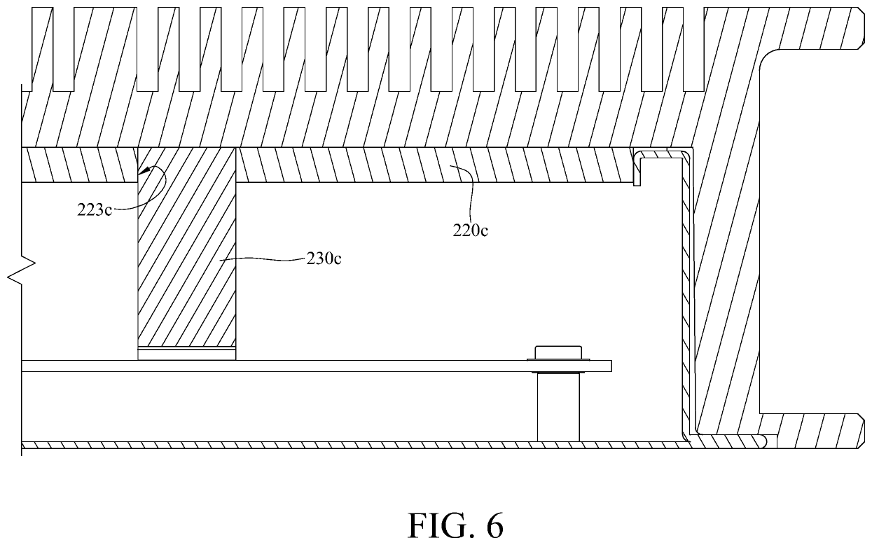

For another example, please refer to FIG. 6, there is shown a cross-sectional view of a mounting plate body 220c and a heat dissipation pillar 230c according to still yet another embodiment of the invention, as shown, the mounting plate body 220c includes a mounting hole 223c. The mounting hole 223c is a through hole having a fixed width, and the heat dissipation pillar 230c is disposed in the mounting hole 223c in a tight-fit manner, but the invention is not limited thereto. In yet another embodiment, the heat dissipation pillar 230c can be fixed at the mounting hole 223c by being adhered to the surface of the mounting plate body 220c that forms the mounting hole 223c.

According to the electronic assembly and the heat dissipation assembly thereof discussed above, the heat dissipation pillars can be partially engaged into the mounting holes of the mounting plate body and therefore to be fixed to the mounting plate body of the fin assembly without using screws. As such, compared to the case that the fin assembly and the heat dissipation pillars are integrally formed, the heat dissipation pillars of the heat dissipation assembly of the invention do not need machining process during manufacturing.

In addition, compared to the case that screwing the heat dissipation pillars one by one, the installation of the heat dissipation pillars of the heat dissipation assembly of the invention is more convenient and efficient.

Accordingly, the heat dissipation assembly of the invention does not involve complex machining process and is convenient and efficient in assembly process, and thus the overall manufacturing cost can be reduced.

Moreover, the electronic assembly and the heat dissipation assembly of the invention can also be applied to vehicles, such as autonomous vehicles (AV), electric vehicles, or a vehicle equipped with an advanced driver assistance systems (ADAS).

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. An electronic assembly, comprising:
a circuit board, comprising a plate body and a heat source disposed on the plate body; and
a heat dissipation assembly, comprising a fin assembly, a mounting plate body, and a heat dissipation pillar, wherein the mounting plate body is fixed to the fin assembly and comprises a mounting hole, the heat dissipation pillar is engaged in the mounting hole of the mounting plate body, one end of the heat dissipation pillar is in thermal contact with the fin assembly, and another end of the heat dissipation pillar is in thermal contact with the heat source of the circuit board.

2. The electronic assembly according to claim 1, wherein the heat dissipation pillar comprises a head part and a body part that are connected to each other, a width of the head part is larger than a width of the body part, the mounting plate body comprises a first side surface and a second side surface that face away from each other, the mounting hole penetrates through the first side surface and the second side surface, the first side surface is fixed to the fin assembly, the mounting hole comprises a wider portion and a narrower portion that are connected to each other, a width of the wider portion is larger than a width of the narrower portion, the wider portion is formed at the first side surface, the narrower portion is formed at the second side surface, the width of the head part ranges between the width of the wider portion and the width of the narrower portion, the width of the body part is smaller than the width of the narrower portion, and the head part is located in the wider portion of the mounting hole so as to be clamped by the fin assembly and the mounting plate body.

3. The electronic assembly according to claim 1, further comprising a plurality of fasteners, the mounting plate body fixed to the fin assembly via the plurality of fasteners.

4. The electronic assembly according to claim 1, wherein the mounting plate body is fixed to the fin assembly via welding.

5. The electronic assembly according to claim 1, wherein the fin assembly comprises a base portion, a plurality of fins and two sidewalls, the base portion comprises a first side surface and a second side surface that face away from each other, the plurality of fins protrude from the first side surface, the two sidewalls stand on the second side surface so that the two sidewalls and the base portion together form an accommodation space therebetween, the mounting plate body is fixed on the second side surface and is located in the accommodation space, and the end of the heat dissipation pillar is in thermal contact with the second side surface of the base portion of the fin assembly.

6. The electronic assembly according to claim 1, wherein quantities of the heat source, the heat dissipation pillar and the mounting hole are plural, the plurality of heat dissipation pillars are respectively in thermal contact with the plurality of heat sources, and the plurality of heat dissipation pillars are respectively engaged in the plurality of mounting holes.

7. The electronic assembly according to claim 1, wherein the mounting plate body comprises a first side surface and a second side surface that face away from each other, the mounting hole penetrates through the first side surface and the second side surface, and a width of the mounting hole is fixed.

8. The electronic assembly according to claim 1, further comprising a base, the base fixed to the fin assembly and the base and the fin assembly together accommodating the circuit board.

9. A heat dissipation assembly, configured to be in thermal contact with a heat source, the heat dissipation assembly comprising:
a fin assembly;
a mounting plate body, fixed to the fin assembly and comprising a mounting hole; and
a heat dissipation pillar, engaged in the mounting hole of the mounting plate body, one end of the heat dissipation pillar in thermal contact with the fin assembly, and another end of the heat dissipation pillar configured to be in thermal contact with the heat source.

10. A heat dissipation assembly, configured to be in thermal contact with a heat source, the heat dissipation assembly comprising:
a fin assembly;
a mounting plate body, being thermally conductive and fixed to the fin assembly; and
a heat dissipation pillar, adhered to the mounting plate body, one end of the heat dissipation pillar in thermal contact with the fin assembly, and another end of the heat dissipation pillar configured to be in thermal contact with the heat source.
